(19) United States
(12) Patent Application Publication
(10) Pub. No.: US 2023/0352274 A1
(43) Pub. Date: Nov. 2, 2023

(54) PLASMA PROCESSING APPARATUS

(71) Applicant: Hitachi High-Tech Corporation, Minato-ku, Tokyo (JP)

(72) Inventors: Hitoshi Tamura, Tokyo (JP); Norihiko Ikeda, Tokyo (JP); Chen Pin Hsu, Tokyo (JP)

(21) Appl. No.: 17/433,693

(22) PCT Filed: Dec. 24, 2020
(86) PCT No.: PCT/JP2020/048422

§ 371 Date: Aug. 25, 2021

(30) Foreign Application Priority Data
Apr. 27, 2020 (WO) PCT/JP2020/017927

(51) Int. Cl. H01J 37/32

(52) U.S. Cl. CPC H01J 37/32311; H01J 37/3222; H01J 37/32229; H01J 37/32247; H01J 2237/334

(57) ABSTRACT

A plasma processing apparatus includes: a vacuum chamber that includes a plasma processing chamber in which a substrate is to be plasma-processed and that can exhaust an inside of the plasma processing chamber to vacuum; and a microwave power supply unit that supplies a microwave power to the vacuum chamber via a circular waveguide. The vacuum chamber includes: a parallel flat plate line portion that is connected to the circular waveguide and receives a microwave power propagated from the circular waveguide; a ring resonator unit that is disposed on an outer periphery of the parallel flat plate line portion and receives the microwave power propagated from the parallel flat plate line portion; a cavity portion that receives a microwave power radiated from a slot antenna formed in the ring resonator unit; and a microwave introduction window that separates the cavity portion from the plasma processing chamber. The parallel flat plate line portion includes a phase adjusting unit for adjusting a phase of microwaves propagating from the parallel flat plate line portion to the ring resonator unit at a boundary portion with the ring resonator unit.

### TECHNICAL FIELD

The present invention relates to a plasma processing apparatus that generates plasma by electromagnetic waves.

### BACKGROUND ART

A plasma processing apparatus is used in production of a semiconductor integrated circuit element. In order to improve a performance of the element and reduce a cost, miniaturization of the element is developed. In the related art, due to two-dimensional miniaturization of the element, the number of elements that can be manufactured by a single target substrate has increased, a manufacturing cost per element has decreased, and at the same time, the performance can be improved due to effects such as shortening a wiring length. However, when dimensions of semiconductor elements are on the order of nanometers, which is close to dimensions of atoms, the difficulty of the two-dimensional miniaturization increases significantly, and new materials and three-dimensional element structures are being applied. Due to these structural changes, the difficulty of manufacturing has increased, and the increase in the manufacturing cost has become a serious problem.

When minute particles or contaminants adhere to the semiconductor integrated circuit element during manufacturing, fatal defects often occur on the semiconductor integrated circuit element. Therefore, the semiconductor integrated circuit element is often manufactured in a clean room in which particles and contaminants are eliminated and a temperature and a humidity are optimally controlled. With the miniaturization of the element, the cleanliness of the clean room required for manufacturing becomes higher, and enormous costs are required for the construction and maintenance of the clean room. Therefore, it is required to efficiently use a space of the clean room for production. From this point of view, miniaturization and cost reduction of a semiconductor manufacturing apparatus is strictly required.

In the plasma processing apparatus that generates plasma by electromagnetic waves, an apparatus in which a static magnetic field is applied to a plasma processing chamber is widely used. This is because the static magnetic field has advantages that loss of the plasma can be prevented and plasma distribution can also be controlled. Furthermore, there is an effect that by using an interaction between the electromagnetic waves and the static magnetic field, the plasma can be generated even under an operation condition where the plasma is usually difficult to be generated. In particular, it is known that when microwaves are used as electromagnetic waves for plasma generation and a static magnetic field that matches a period of electron cyclotron operation with a frequency of the microwaves is used, an electron cyclotron resonance (hereinafter, referred to as ECR) phenomenon occurs. Since the plasma is mainly generated in a region where ECR occurs, there are effects that by adjusting a distribution of the static magnetic field, a plasma generation region can be controlled and conditions under which the plasma can be generated by the ECR phenomenon can be widely ensured.

An RF bias technique is used to speed up plasma processing and improve processing quality by applying a radio frequency to a target substrate under the plasma processing and attracting ions in the plasma onto a surface of the target substrate. For example, in a case of plasma etching processing, since the ions are vertically incident on a surface to be processed of the target substrate, anisotropic processing in which etching proceeds only in a vertical direction of the target substrate is achieved.

As an example corresponding to the above problems and technique trends in the related art, a plasma processing apparatus described in PTL 1 is provided with an electromagnet for applying a static magnetic field around a processing chamber, and can apply the static magnetic field to the processing chamber. Further, the electromagnet is formed of electromagnets of multiple stages, and a static magnetic field distribution in the processing chamber can be adjusted by adjusting a current value supplied to each electromagnet.

In PTL 1, microwaves having a frequency of 2.45 GHz are used as electromagnetic waves for generating plasma, and are circularly polarized by a circularly polarized wave generator and are supplied to an apparatus using a circular waveguide disposed on a central axis of the apparatus. An output end of the circular waveguide is connected to a branch circuit, and the branch circuit is formed of a plurality of waveguides disposed at equal angles. In an embodiment, a rectangular waveguide that is branched into four at equal angles every 90 degrees is used as the branch circuit. Furthermore, a ring resonator is excited by the plurality of waveguides in the branch circuit. A slot antenna is provided on the processing chamber side of the ring resonator, and in the ring resonator, microwaves are radiated from the slot antenna to the processing chamber according to an electromagnetic field formed in a resonance mode.

The static magnetic field in the processing chamber of PTL 1 is controlled to a desired distribution by the electromagnet, and interacts with introduced microwaves to generate plasma in the processing chamber. By using the electromagnet, the static magnetic field that causes the ECR can be generated in the processing chamber, and the distribution can be adjusted to control diffusion of the plasma.

As described above, the circularly polarized microwaves are introduced into the circular waveguide of PTL 1. Accordingly, traveling waves are excited in the ring resonator. Electromagnetic waves having a plurality of wavelengths are excited in the ring resonator in one round in an azimuth direction, but when standing waves are excited, a non-uniformity in the azimuth direction corresponding to antinodes and nodes of the standing waves exists at a fixed position. By exciting the traveling waves in the resonator, electromagnetic waves that are uniform in the azimuth direction are excited in time.

### CITATION LIST

### Patent Literature

PTL 1: JP-A-2012-190899

### SUMMARY OF INVENTION

### Technical Problem

Generally, the plasma is often lost on a wall surface of the plasma processing chamber, and tends to have a density that is low near the wall surface and high near a center away from the wall surface. As a result, the plasma density on the target substrate tends to be convexly distributed, and a uniformity of the plasma processing may become a problem.

The plasma has a property of tending to diffuse in a direction along the lines of magnetic force, but being prevented from the diffusion in a direction perpendicular to the lines of magnetic force. Furthermore, it is possible to control the plasma generation region by adjusting a position of an ECR surface and the like. In this way, the distribution of the plasma can be adjusted by adjusting the diffusion and the generation region of the plasma using the static magnetic field.

However, it may not be possible to obtain a desired adjustment range only by a unit that adjusts the plasma density distribution by the static magnetic field, and thus an additional unit for adjustment is further desired.

For example, in the case of etching processing, a film thickness obtained by processing may be, for example, large at a center of the target substrate and small at an outer peripheral side, or conversely, small at the center and larger at the outer peripheral side, depending on characteristics of film forming apparatuses. It may be desired to correct by the etching processing the non-uniformity caused by these film forming apparatuses so as to perform uniform processing as a whole. It may be desired to adjust the plasma density distribution on the target substrate to a desired distribution in this way.

Generally, if an etching rate is uniform, a reaction product is uniformly produced and released from each part of the target substrate. As a result, a density of the reaction product is high in a central portion of the target substrate, and is low in an outer peripheral portion. When the reaction product reattaches to the target substrate, etching is inhibited and the etching rate decreases. A probability that the reaction product reattaches to the target substrate is affected by many parameters such as a temperature of the target substrate, a pressure in the processing chamber, and a surface condition of the target substrate. Therefore, in order to obtain uniform etching processing in a plane of the target substrate, it may be necessary to intentionally adjust the plasma density distribution on the target substrate to be non-uniform.

As shown above, a plasma processing apparatus capable of easily controlling the plasma density distribution on the target substrate is desired.

By using the ring resonator, it is possible to obtain a low electromagnetic field distribution near the center and a high electromagnetic field distribution near the outer periphery, and thereby obtaining a low plasma density distribution at the center and a high plasma density distribution at the outer peripheral portion. When considering the property that the plasma tends to diffuse and have a high density distribution near the center, in order to obtain uniform plasma on the target substrate, it is essential to adjust the density distribution to be low at the center and high at the outer peripheral portion in the plasma generation region.

In PTL 1, the ring resonator is excited by waveguides evenly disposed in four azimuth directions. However, in this case, the non-uniformity of the electromagnetic field in the ring resonator may occur due to four connection portions of the waveguide, and accordingly, the non-uniformity of the plasma distribution may become apparent. Further, since a structure such as branching is complicated, a manufacturing cost, a difference between apparatuses, and the like may become a problem, and a simple excitation structure is desirable.

The invention provides a plasma processing apparatus capable of solving the above-described problems in the related art and uniformly exciting a ring resonator with a simple structure.

### Solution to Problem

In order to solve the above-described problems, in the invention, a plasma processing apparatus includes: a vacuum chamber that includes a plasma processing chamber in which a substrate is to be plasma-processed and that can exhaust an inside of the plasma processing chamber to vacuum; and a microwave power supply unit that supplies a microwave power to the vacuum chamber via a circular waveguide. The vacuum chamber includes: a parallel flat plate line portion that is connected to the circular waveguide and receives a microwave power propagated from the circular waveguide; a ring resonator unit that is disposed on an outer periphery of the parallel flat plate line portion and receives the microwave power propagated from the parallel flat plate line portion; a cavity portion that receives a microwave power radiated from a slot antenna formed in the ring resonator unit; and a microwave introduction window that separates the cavity portion from the plasma processing chamber. The parallel flat plate line portion includes a phase adjusting unit for adjusting a phase of microwaves propagating from the parallel flat plate line portion to the ring resonator unit at a boundary portion with the ring resonator unit.

Further, in order to solve the above-described problems, in the invention, a plasma processing apparatus includes: a vacuum chamber that includes a plasma processing chamber in which a substrate is to be plasma-processed and that can exhaust an inside of the plasma processing chamber to vacuum; a circular waveguide that is disposed on a central axis of the vacuum chamber and that has a circular cross section; a parallel flat plate line portion that is connected to an output end of the circular waveguide on the vacuum chamber side and that has a propagation direction of a microwave power propagated from the circular waveguide perpendicular to the central axis of the vacuum chamber; a ring resonator unit that is connected to an outer periphery of the parallel flat plate line portion and resonates a microwave power propagated from the parallel flat plate line portion at a plurality of wavelengths in an azimuth direction with respect to the central axis of the vacuum chamber, and that has a slot antenna that radiates the resonated microwave power formed therein; a cavity portion that receives the microwave power radiated from the slot antenna formed in the ring resonator unit; and a microwave introduction window that separates the cavity portion from the plasma processing chamber.

### Advantageous Effect

According to the invention, an electromagnetic field distribution in a ring resonator can be accurately adjusted to a desired resonance mode with a simple structure, and an unnecessary electromagnetic field distribution that causes a bias of a plasma distribution can be prevented. Therefore, plasma processing having a good uniformity can be applied on a target substrate.

### BRIEF DESCRIPTION OF DRAWINGS

FIG. 1 is a cross-sectional view of a side surface showing a schematic configuration of a microwave plasma etching apparatus according to a first embodiment.

FIG. 2 is a cross-sectional view taken along a line AA in FIG. 1 of the microwave plasma etching apparatus according to the first embodiment.

FIG. 3A is a cross-sectional view corresponding to the cross-sectional view taken along the line AA in FIG. 1 showing a modification of a parallel flat plate line in the microwave plasma etching apparatus according to the first embodiment.

FIG. 3B is a cross-sectional view corresponding to the cross-sectional view taken along the line AA in FIG. 1 showing another modification of the parallel flat plate line in the microwave plasma etching apparatus according to the first embodiment.

FIG. 4 is a horizontal cross-sectional view near a parallel flat plate line of a microwave plasma etching apparatus according to a second embodiment.

FIG. 5 is a horizontal cross-sectional view near a parallel flat plate line of a microwave plasma etching apparatus according to a third embodiment.

FIG. 6A is a cross-sectional view of a side surface showing a schematic configuration of a microwave plasma etching apparatus according to a fourth embodiment.

FIG. 6B is a cross-sectional view taken along a line BB in FIG. 6A of the microwave plasma etching apparatus according to the fourth embodiment.

FIG. 7 is a vertical cross-sectional view near a circular waveguide of a microwave plasma etching apparatus showing a modification of the fourth embodiment.

FIG. 8 is a plan view of a conductor plate of a ring resonator according to a modification of the present embodiment, which corresponds to the cross-sectional view taken along the line BB of FIG. 6A of the microwave plasma etching apparatus according to the fourth embodiment.

### DESCRIPTION OF EMBODIMENTS

The invention can adjust a distribution of a microwave power in a plasma processing apparatus that generates plasma by electromagnetic waves, thereby controlling a distribution of plasma generated in a processing chamber so as to enable high-quality plasma processing.

The invention is a microwave ECR plasma processing apparatus including: a ring resonator that resonates in a mode having electromagnetic waves of m wavelengths in an azimuth direction; a waveguide disposed coaxially with a central axis of the ring resonator; and a parallel flat plate line that propagates the electromagnetic waves propagated from the waveguide to the ring resonator. Therefore, the invention can increase excitation points such that the inside of the ring resonator can be excited evenly, so as to improve an axisymmetry of the generated plasma and reduce a microwave power loss. Furthermore, by simplifying a structure, a difference between apparatuses (machine difference) can be reduced.

By using the ring resonator, an electromagnetic field distribution excited in the processing chamber can be adjusted to a ring-shaped distribution which is low at a center and high at an outer peripheral portion. Therefore, it is easy to generate plasma in a ring shape in the processing chamber. On the other hand, as described above, due to an effect of a plasma loss on a wall surface of the processing chamber and an effect of plasma diffusion, a plasma density near the wall surface tends to decrease, and a high density distribution tends to be easily obtained near the center.

On the other hand, in the invention, a positional relationship between the wall surface of the processing chamber and the ring-shaped plasma generation distribution by the ring resonator is adjusted such that a uniform plasma distribution can be obtained on a wafer. Further, the invention includes: a circular waveguide having a circular cross section disposed on a central axis of a substantially axisymmetric plasma processing apparatus; a plasma processing chamber in which a target substrate is to be plasma-processed; a parallel flat plate line connected to an output end of the circular waveguide; a ring resonator having a microwave propagation direction in the parallel flat plate line perpendicular to the central axis and that resonates at a plurality of wavelengths in an azimuth direction; and an antenna that is provided on the plasma processing chamber side of the ring resonator and radiates electromagnetic waves in the ring resonator to the plasma processing chamber. The output end of the parallel flat plate line is connected to the ring resonator, and the ring resonator is evenly excited at a connection surface between the parallel flat plate line and the ring resonator, so that a uniform plasma distribution can be obtained on the wafer.

Hereinafter, an embodiment according to the invention will be described in detail with reference to drawings. In all the drawings for describing the present embodiment, components having the same function are denoted by the same reference numerals, and the repetitive description thereof will be omitted in principle.

However, the invention should not be construed as being limited to description of the embodiments described below. Those skilled in the art could have easily understood that specific configurations can be changed without departing from the spirit or gist of the invention.

### First Embodiment

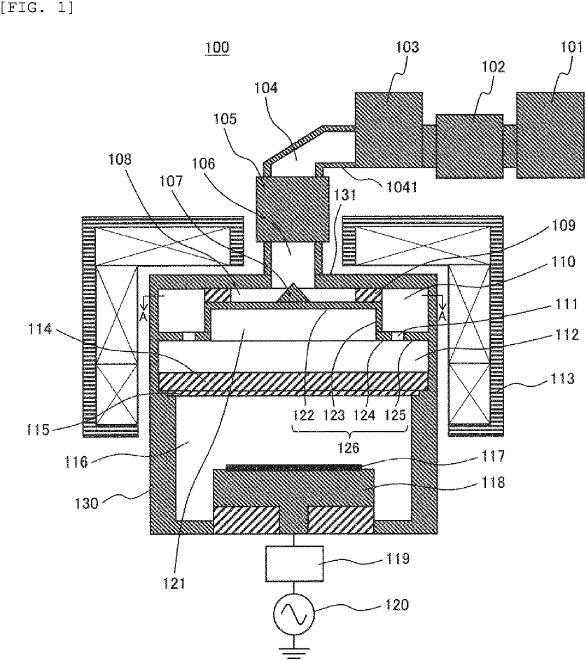

A microwave plasma etching apparatus 100 will be described with reference to FIG. 1 as an example of the plasma processing apparatus using the invention.

FIG. 1 shows a vertical cross-sectional view of the entire microwave plasma etching apparatus 100. In a configuration shown in FIG. 1, 101 is a microwave oscillator (microwave power supply), 102 is an isolator, 103 is an automatic matcher, 1041 is a rectangular waveguide, 104 is a circular rectangle converter, 105 is a circularly polarized wave generator, 106 is a circular waveguide, 107 is a matching block, 108 is a parallel flat plate line, 109 is a phase adjusting unit, 110 is a ring resonator, 111 is a slot antenna, 112 is a cavity portion, 121 is an inner cavity portion, 126 is an inner cavity forming portion forming the inner cavity portion 121, 122 is an upper surface portion of the inner cavity forming portion 126, 123 is a side surface portion of the inner cavity forming portion 126, 124 is an inner edge portion of the inner cavity forming portion 126, and 125 is an outer edge portion of the inner cavity forming portion 126.

113 is a static magnetic field generator, 114 is a microwave introduction window, 115 is a shower plate, 116 is a plasma processing chamber, 117 is a target substrate, 118 is a substrate electrode, 119 is an automatic matcher, 120 is an RF bias power supply, and 130 is a vacuum chamber.

In the configuration shown in FIG. 1, a gas supply system that supplies gas to the plasma processing chamber 116, a vacuum exhaust unit that exhausts the inside of the plasma processing chamber 116 to vacuum, and a control unit that controls the microwave oscillator 101 and the automatic matcher 103, the static magnetic field generator 113, the RF bias power supply 120, and the like are not shown.

In the above configuration, microwaves having a frequency of 2.45 GHz output from the microwave oscillator 101 is propagated to the circular rectangle converter 104 via the isolator 102 and the automatic matcher 103 by the rectangular waveguide 1041. A magnetron is used as the microwave oscillator 101. The circular rectangle converter 104 also serves as a corner that bends a traveling direction of the microwaves by 90 degrees to reduce a size of the entire apparatus.

The circularly polarized wave generator 105 is connected to a lower portion of the circular rectangle converter 104 to convert the microwaves incident as linearly polarized waves into circularly polarized waves. Furthermore, the circular waveguide 106 provided on a substantially central axis of the vacuum chamber 130 forming the plasma processing chamber 116 is provided on the side of the plasma processing chamber 116 of the circularly polarized wave generator 105, and the circularly polarized microwaves are propagated.

The parallel flat plate line 108, which is formed in a manner of being sandwiched between the upper surface portion 122 of the inner cavity forming portion 126 and an upper conductor 131 which is an upper surface of the vacuum chamber 130, is connected to an end portion of the circular waveguide 106 via the matching block 107. The circular waveguide 106 and the parallel flat plate line 108 are orthogonal to each other, and a microwave power propagated from the circular waveguide 106 to the parallel flat plate line 108 changes the traveling direction thereof.

The matching block 107 is a highly conductive metal block having a function of preventing reflection of the microwave power at a connection portion between the circular waveguide 106 and the parallel flat plate line 108, and has a conical shape in the present embodiment.

On an upper side surface of the vacuum chamber 130, the parallel flat plate line 108 is connected to the ring resonator 110 formed by a space sandwiched between the side surface portion 123 of the inner cavity forming portion 126, the inner edge portion 124, and the outer edge portion 125. The microwave power propagated from the circular waveguide 106 is supplied into the ring resonator 110.

In the parallel flat plate line 108, the phase adjusting units 109 are loaded near a boundary portion with the ring resonator 110. The phase adjusting units 109 functions to reduce mismatch of a microwave electromagnetic field distribution on a connection surface between the ring resonator 110 and the parallel flat plate line 108. The phase adjusting units 109 can excite a desired resonance mode in the ring resonator 110 by reducing the mismatch of the microwave electromagnetic field distribution on the connection surface between the ring resonator 110 and the parallel flat plate line 108.

In the present embodiment, dielectric blocks are used as the phase adjusting units 109. The phase adjusting units 109 are not limited thereto, and other structures, for example, a structure having a stub having a protrusion, a groove or a linear protrusion on an inner surface of the parallel flat plate line 108 may be used.

The slot antenna 111 is provided on a lower portion of the ring resonator 110 as a microwave radiation unit, and the cavity portion 112 is provided on a lower portion of the slot antenna 111. The slot antenna 111 is formed by a space sandwiched between an outer peripheral surface of the inner edge portion 124 of the inner cavity forming portion 126 and an inner peripheral surface of the outer edge portion 125.

Microwaves having an electromagnetic field distribution excited in the desired resonance mode inside the ring resonator 110 are radiated from the slot antenna 111 to the cavity portion 112 on the lower portion. The inner cavity portion 121 formed by the upper surface portion 122 and the side surface portion 123 of the inner cavity forming portion 126 is provided inside the ring resonator 110, and the inner cavity portion 121 and the cavity portion 112 have a function of adjusting the electromagnetic field distribution of microwaves radiated from the slot antenna 111.

The lower portion of the cavity portion 112 is separated from the plasma processing chamber 116 by the microwave introduction window 114 and the shower plate 115. Quartz is used for the microwave introduction window 114 and the shower plate 115 as a material that has a small microwave loss and is unlikely to adversely affect plasma processing such as generation of particles.

The inner cavity portion 121 inside the ring resonator 110 and the cavity portion 112 have a function of adjusting the electromagnetic field distribution of the microwaves radiated from the slot antenna 111. The plasma processing chamber 116 is provided below the shower plate 115, and plasma is generated by the radiated microwave power.

The gas supply system (not shown) and a vacuum exhaust system (not shown) are connected to the plasma processing chamber 116, and a gas atmosphere and a pressure suitable for plasma processing are controlled. The plasma processing chamber 116 and the cavity portion 112 are separated by the microwave introduction window 114, the cavity portion 112 side is in an atmospheric pressure state, and the plasma processing chamber 116 side is exhausted and is maintained in a vacuum state.

Processing gas is supplied from the gas supply system (not shown) in a minute gap (not shown) between the microwave introduction window 114 and the shower plate 115, and is supplied to the inside of the plasma processing chamber 116 through a plurality of minute supply holes (not shown) provided in the shower plate 115.

Inside the plasma processing chamber 116, the substrate electrode 118 for placing the target substrate 117 is disposed in a state of being electrically insulated from the plasma processing chamber 116. The RF bias power supply 120 is connected to the substrate electrode 118 via the automatic matching unit 119, and an RF bias can be applied to the target substrate 117.

The static magnetic field generator 113 for applying the static magnetic field is provided around the plasma processing chamber 116. In the present embodiment, the static magnetic field generator 113 is formed of a multi-stage solenoid coil, and can adjust the distribution of the static magnetic field applied to the plasma processing chamber 116 by adjusting direct currents supplied by a plurality of direct power sources (not shown). A permanent magnet or a magnetic material may be used in combination as a unit for generating a static magnetic field together with the static magnetic field generator 113 or in place of the static magnetic field generator 113.

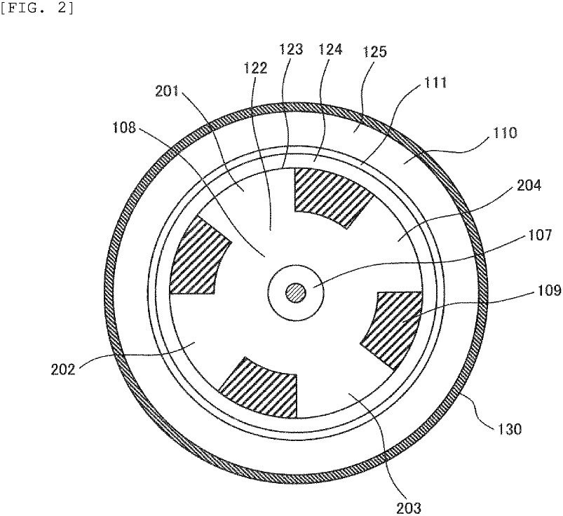

FIG. 2 shows a cross-sectional view taken along a line AA in FIG. 1, that is, a horizontal cross-sectional view near the parallel flat plate line 108. As described above, the dielectric blocks, as the phase adjusting units 109, are loaded in the parallel flat plate line 108. In PTL 1, the ring resonator is excited by four rectangular waveguides, but in the present embodiment, as shown in FIG. 2, the ring resonator is excited by the parallel flat plate line 108 provided with the phase adjusting unit 109. In a configuration shown in FIG. 2, the four phase adjusting units 109 are disposed at equal intervals, and a width of each of the four phase adjusting units 109 in a circumferential direction is formed to have the same dimension as a width of an interval between the adjacent phase adjusting units 109.

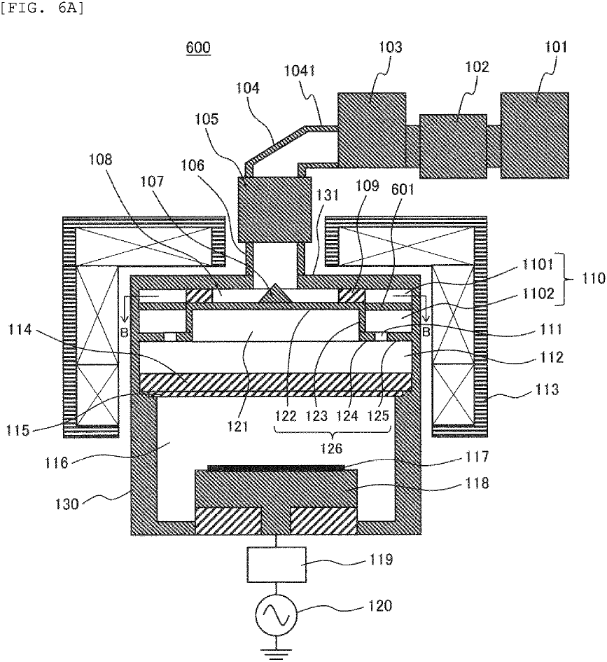

The electromagnetic field in the ring resonator 110 uses a mode (hereinafter, referred to as a TM51 mode) that resonates at 5 wavelengths in the azimuth direction as described in PTL 1. Further, the circular waveguide 106 on the central axis uses a TE11 mode, which is a mode of the lowest order, also as described in PTL 1. In the TE11 mode, the phase changes 360 degrees in one round, 360 degrees in the azimuth direction, and in the TM51 mode of the ring resonator, the phase changes 360 degrees × 5 wavelengths in one round, 360 degrees in the azimuth direction. Therefore, as shown in FIG. 5 of PTL 1, the phases of the electromagnetic waves in the TE11 mode and the TM51 mode match at four portions every 90 degrees, and the ring resonator is excited using these four portions.

On the other hand, in the present embodiment, the phases in the TE11 mode and the TM51 mode match at four connection portions (regions 201, 202, 203, and 204 sandwiched by the adjacent phase adjusting units 109 in FIG. 2) not including the phase adjusting units 109.

On the other hand, four dielectric blocks are used as the phase adjusting units 109. It is generally known that a wavelength of electromagnetic waves in a substance having a refractive index n is shortened to a length of 1/n as compared with that in vacuum or an atmosphere. In the present embodiment, quartz is used as a material of the four dielectric blocks as the phase adjusting units 109. It is known that a refractive index of quartz is about 2, and the wavelength of the electromagnetic waves in quartz is shortened by about half.

The wavelength of the microwaves propagating in the parallel flat plate line 108 is also shortened in the dielectric blocks as the phase adjusting units 109, and the phase thereof changes as compared with the microwaves that do not pass through the dielectric blocks. The TM51 mode of the ring resonator can be excited accurately by adjusting an amount of phase change such that the electromagnetic waves in the TM51 mode and the TE11 mode roughly match on a connection surface (in FIG. 2, an upper portion of the side surface portion 123 of the inner cavity forming portion 126) between the ring resonator 110 and the parallel flat plate line 108. This is equivalent to matching the phases in the TE11 mode and the TM51 mode at eight portions including the four connection portions that include the phase adjusting units 109 in addition to the four connection portions that do not include the phase adjusting units 109.

When the phases are to be matched in the same eight portions by using the waveguides described in PTL 1, it is necessary to adjust the phase in each of the eight-branched waveguides, which has a drawback that the structure becomes complicated. Further, the method of exciting by the four waveguides in PTL 1 has a drawback that a non-uniformity due to the waveguide connection portions occurs as described above and a deviation from the desired TM51 mode becomes large.

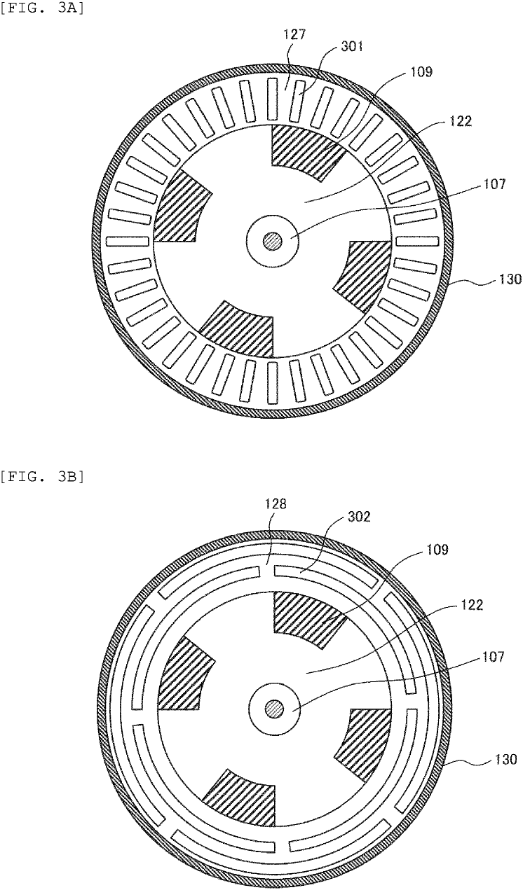

On the other hand, in the present embodiment described with reference to FIG. 2, an example in which a slot antenna 111 that is annular in the azimuth direction is formed is described, but instead of the annular slot antenna 111, antennas having other shapes such as multiple slot antennas 301 formed radially on an edge portion 127 corresponding to the inner edge portion 124 and the outer edge portion 125 of the inner cavity forming portion 126 as shown in FIG. 3A, or a plurality of arc-shaped slot antennas 302 on a plurality of concentric circles on an edge portion 128 corresponding to the inner edge portion 124 and the outer edge portion 125 of the inner cavity forming portion 126 as shown in FIG. 3B may be used.

According to the present embodiment, by increasing the excitation points, the inside of the ring resonator 110 can be resonated more evenly, and therefore, the axisymmetry of the generated plasma can be improved.

Further, according to the present embodiment, the loss of the microwave power can be reduced by simplifying a branch structure to the plurality of waveguides described in PTL 1 into the parallel flat plate line 108, and a manufacturing cost and differences between apparatuses can be reduced.

Further, according to the present embodiment, the ring resonator 110 is excited evenly on the connection surface between the parallel flat plate line 108 and the ring resonator 110, and therefore, the electromagnetic field distribution in the ring resonator 110 is uniformly excited.

Further, according to the present embodiment, by providing the phase adjusting units 109 in the parallel flat plate line 108, it is possible to more accurately match the electromagnetic field in the ring resonator 110 with the electromagnetic field on the connection surface of the parallel flat plate line 108, and the ring resonator 110 is uniformly excited.

Further, according to the present embodiment, by applying the circularly polarized waves to the circular waveguide 106 using the circularly polarized wave generator 105, traveling waves in the ring resonator 110 can be excited, generation of standing waves in the ring resonator 110 can be prevented, and uniform plasma can be generated.

Further, according to the present embodiment, the traveling waves can be excited in the ring resonator even when linearly polarized waves are applied to the circular waveguide by performing phase adjustment by the phase adjusting unit in detail.

### Second Embodiment

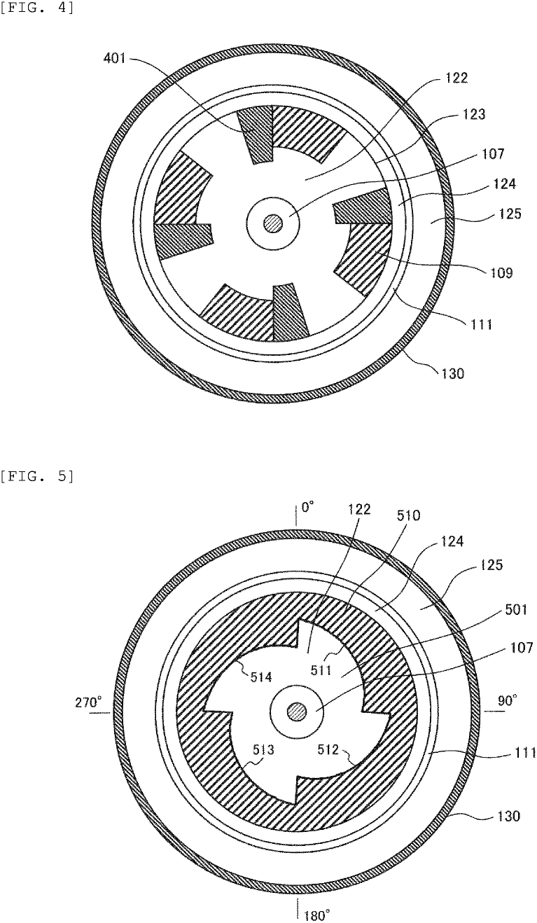

As a second embodiment, FIG. 4 corresponding to the cross-sectional view taken along the line AA in FIG. 1 shows a horizontal cross-sectional view near the parallel flat plate line 108 when ridges 401 are added in addition to the phase adjusting units 109. Since the configuration of the apparatus except for the vicinity of the parallel flat plate line 108 is the same as that of the first embodiment shown in FIG. 1, only differences will be described with reference to FIG. 4.

In the configuration near the parallel flat plate line 108 according to the present embodiment shown in FIG. 4, a ridge 401 is added adjacent to each phase adjusting unit 109. The ridge 401 is implemented by a conductive column connecting the upper surface portion 122 of the inner cavity forming portion 126 and the upper conductor 131 as the upper surface of the vacuum chamber 130, which form the parallel flat plate line 108.

When the annular slot antenna 111 formed between the inner edge portion 124 of the inner cavity forming portion 126 and the outer edge portion 125 of the inner cavity forming portion 126 as shown in FIG. 2 is used as a slot antenna, a structure is formed in which the inner edge portion 124 of the inner cavity forming portion 126 as an inner conductor plate of the slot antenna 111 and the outer edge portion 125 as an outer conductor plate are not in contact with each other, and the upper surface portion 122 as a lower conductor of the parallel flat plate line 108 is fixed to the upper conductor only by the phase adjusting units 109. By using the ridges 401, the upper and lower conductor plates of the parallel flat plate line 108 can be stably held.

In general, the traveling waves can be excited by exciting positions in the waveguide between which a path length difference is ¼ wavelength with a phase difference of 90 degrees. A case is considered that by using the method, for example, the traveling waves are excited in a ring resonator that resonates in the mode of 5 wavelengths in the azimuth direction by a circular waveguide in the TE11 mode provided on the central axis of the ring resonator.

An azimuth difference corresponding to the ¼ wavelength in the ring resonator is 18 degrees. The TE11 mode of the circular waveguide is a mode that shows a 360-degree phase change for one wavelength in the azimuth direction in a cross section of the waveguide, and therefore, a phase difference in the TE11 mode of the circular waveguide is 18 degrees with respect to the azimuth difference of 18 degrees. In order to have a phase difference of 90 degrees with an excitation source having a phase difference of 18 degrees, a subtraction phase difference of 72 degrees may be given. A dielectric material having a wavelength shortening effect can be used to give the phase difference of 72 degrees. It can be seen that the traveling waves can be excited in the ring resonator by giving the phase difference of 72 degrees every 18 degrees of increase of the azimuth.

According to the present embodiment, in addition to the effects described in the first embodiment, by providing the structure using the ridges 401 that short-circuits between conductor plates in the parallel flat plate line 108, the parallel flat plate line 108 can be stably held and the ring resonator 110 can be excited uniformly.

### Third Embodiment

As a third embodiment, FIG. 5 shows only a horizontal cross-sectional view near the parallel flat plate line 108 corresponding to the cross-sectional view taken along the line AA in FIG. 1. Only the differences from the first embodiment shown in FIGS. 1 and 2 will be described with reference to FIG. 5.

As described above, by exciting a plurality of positions of the ring resonator 110 with a predetermined phase difference, traveling waves can be excited in the ring resonator 110. In the first embodiment and the second embodiment, the phase adjusting units 109 are implemented by four dielectric blocks. On the other hand, in the present embodiment, as shown in FIG. 5, a disk-shaped dielectric material having a specially shaped opening portion 501 is used as a phase adjusting unit 510.

As described above, a wavelength of electromagnetic waves propagating in a dielectric material is shortened according to a refractive index, and a phase thereof is changed according to a path length. The phase adjusting unit 510 according to the present embodiment has a hole shape such that as an azimuth increases from 0 degrees to less than 90 degrees, a radius of an end surface from a center increases monotonically as indicated by 511. Similarly, the phase adjusting unit 510 has a hole shape in which as the azimuth increases from 90 degrees or more to less than 180 degrees, from 180 degrees or more to less than 270 degrees, and from 270 degrees or more to less than 360 degrees as an end surface is indicated by 512, the radius from the center of end surfaces also decreases monotonously, as indicated by 512, 513, and 514, respectively. Further, the end surfaces 511, 512, 513, and 514 are formed such that the azimuths at positions separated by 90 degrees from each other have the same radius.

The microwaves excited in the TE11 mode of the circular waveguide 106 and propagated in each azimuth direction of the parallel flat plate line 108 are phase-controlled by the phase adjusting unit 510 having such shape, and reach the connection surface with the ring resonator 110. By adjusting a degree of monotonous decrease of the radius, the phase at the connection surface can be accurately approximated to the traveling waves corresponding to the TM51 mode of the ring resonator 110. Accordingly, the traveling waves can be excited in the ring resonator 110. In this case, the circularly polarized wave generator 105 loaded in the circular waveguide 106 can be omitted. Further, by using together instead of omitting the circularly polarized wave generator 105, it is possible to generate the traveling waves in a wider plasma generation condition range.

According to the present embodiment, the same effect as described in the first embodiment can be obtained. Although the ring resonator that resonates in the mode of 5 wavelengths in the azimuth direction has been described above as an example, a ring resonator that resonates in another resonance mode may be used.

### Fourth Embodiment

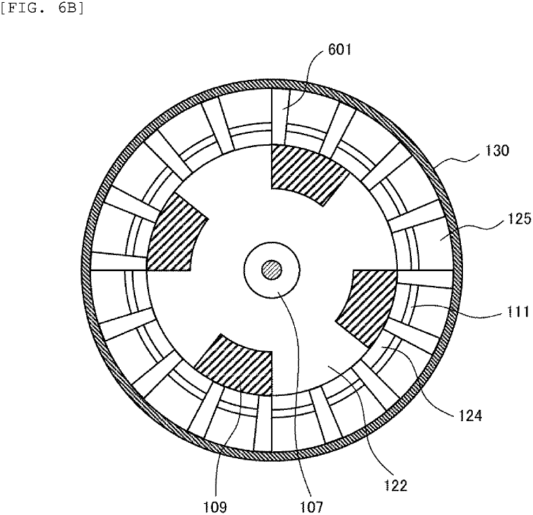

As a fourth embodiment, FIGS. 6A to 8 are used for an example of a microwave plasma etching apparatus 600 having a configuration in which a conductor plate for removing an electric field in an unnecessary mode is inserted inside the ring resonator 110. Therefore, only differences from the first embodiment described with reference to FIGS. 1 and 2 will be described.

In the microwave plasma etching apparatus 600 shown in FIGS. 6A to 8 according to the present embodiment, those having the same configuration as that of the microwave plasma etching apparatus 100 described with reference to FIGS. 1 to 3B in the first embodiment are assigned the same numbers, and the description thereof will be omitted. In the microwave plasma etching apparatus 600 shown in FIG. 6A, a display of an exhaust system is omitted as in the microwave plasma etching apparatus 100 of FIG. 1.

When an experiment is performed by changing plasma generation conditions such as a pressure and a microwave power using the microwave plasma etching apparatus 100 having the configuration described in the first embodiment, a non-axisymmetry may appear in an etching rate distribution on a wafer. When examining the cause, it has been discovered that unnecessary modes other than the desired mode is mixed in the electromagnetic field distribution in the ring resonator.

Therefore, a structure that prevents unnecessary modes is discussed, and as a result, an obtained structure is shown in FIGS. 6A and 6B. FIG. 6A is a cross-sectional view of a side surface showing a schematic configuration of the microwave plasma etching apparatus 600 according to the present embodiment, and FIG. 6B is a cross-sectional view taken along a line BB of FIG. 6A.

The microwave plasma etching apparatus 600 in the present embodiment is characterized by a configuration in which a plurality of plates 601 formed of conductor plates for removing electric fields in unnecessary modes are radially loaded, at equal intervals, in the ring resonator 110 of the microwave plasma etching apparatus 100 of FIG. 1 described in the first embodiment. As shown in FIG. 6A, the ring resonator 110 is vertically divided into an upper resonance chamber 1101 and a lower resonance chamber 1102 by the plates 601 as the conductor plates.

A height direction of FIG. 6A is set to a thickness of the plates 601. As shown in FIG. 6B, the plates 601 are disposed at equal intervals radially with respect to the central axis of the ring resonator 110, and the upper resonance chamber 1101 and the lower resonance chamber 1102 communicate with each other between the adjacent plates 601.

Further, the plates 601 which are conductor plates are made of aluminum as a high conductivity material having a small loss for microwaves. Further, the loss can be further reduced by plating the surface thereof with silver or gold, which has a high conductivity.

It is generally known that when a perfect conductor is loaded in an electromagnetic field, an electric field component is perpendicular to a perfect conductor surface. That is, when the perfect conductor surface is loaded perpendicular to an original electric field distribution, the original electric field distribution is not affected. On the other hand, when an electric field component parallel to the perfect conductor surface exists, the electric field component is short-circuited on the surface of the perfect conductor and the electric field component parallel to the surface becomes zero, and therefore, the original electric field distribution is changed.

By using this property and loading a perfect conductor plate perpendicular to the electric field with respect to a desired electromagnetic field distribution, a mode having an electric field component parallel to a perfect conductor plate distribution can be prevented without affecting the desired electromagnetic field.

In the case of the present embodiment, the electric field in the desired mode inside the ring resonator 110 is an electric field having only a component in a vertical direction in FIG. 6A. Therefore, if a perfect conductor plate having a surface perpendicular to the electric field is loaded inside the ring resonator 110, a mode having a component parallel to the surface of the perfect conductor plate can be prevented (reduced) without affecting the desired mode. The perfect conductor plate is simulated with a high conductivity material. The higher the conductivity of the material, the more a power loss for the desired mode can be reduced.

At radio frequencies of microwaves and the like, it is known that an electromagnetic field cannot penetrate inside a material having a high conductivity, and an electromagnetic field exists only on the surface, which is called a skin effect. Therefore, the conductivity of the surface of the plates 601 as conductor plates is important, and a method such as covering only the surface of the plates 601 with a material having a high conductivity may be used.

That is, in a modification, the plates 601 as the conductor plates in the microwave plasma etching apparatus 600 shown in FIG. 6A are formed of a highly conductive material made of aluminum, and the plurality of plates are disposed at equal intervals as shown in FIG. 6B. With such a configuration, it is possible to set the microwaves radiated from the slot antenna 111 on the lower portion of the ring resonator 110 into the cavity portion 112 to the desired mode. Accordingly, plasma having a desired distribution is generated inside the plasma processing chamber 116, and a uniformity of plasma processing with respect to the target substrate 117 can be improved.

By configuring the microwave plasma etching apparatus 600 as shown in the present embodiment, when a microwave power oscillated by the microwave power supply 101 propagates through the parallel flat plate line 108 and supplied to the ring resonator 110 resonates between the upper resonance chamber 1101 and the lower resonance chamber 1102 of the ring resonator 110, an electric field component having a component parallel to the surface of the plates 601 is short-circuited on the surface of the plates 601 and disappears. As a result, the microwaves resonated inside the ring resonator 110 are in the desired mode, which has an electric field component that is mainly perpendicular to the plates 601.

In a state where an electric field in such a desired mode is formed in the ring resonator 110, as described in the first embodiment, the microwaves are radiated from the annular slot antenna 111 formed on the lower portion of the ring resonator 110 into the cavity portion 112.

Instead of the slot antenna 111 of the ring resonator 110, the slot antennas 301 shown in FIG. 3A or the slot antennas 302 shown in FIG. 3B may be used.

Further, as the configuration of the parallel flat plate line 108, the configuration in which the ridges 401 are added to the phase adjusting unit 109 as shown in FIG. 4 described in the second embodiment, or a configuration in which the phase adjusting units 109 are replaced with the phase adjusting unit 510 described with reference to FIG. 5 in the third embodiment may be used.

Here, in general, if there is a discontinuous portion in a transmission path of microwaves, reflected waves are generated at that position and the transmitted power is reduced. In the microwave plasma etching apparatus 600 according to the present embodiment, ideally, it is desirable to transmit the microwave power with as few discontinuous portions as possible in the transmission path of the microwave power from the microwave power supply 101 to the plasma processing chamber 116 in which a plasma generation region as a load is formed.

However, there are cases where a discontinuous portion such as the plates 601 loaded inside the ring resonator 110 must be formed for the purpose of controlling the electromagnetic field distribution. When such a discontinuous portion is provided in the transmission path of the microwaves, there is a concern that the transmission power may decrease due to the discontinuous portion. Especially in the case of a complicated structure as in the present embodiment, prevention of the reflected waves is important.

In order to prevent the reflected waves, a method of canceling the reflected waves by superimposing waves having the same amplitude and an inverted phase on the reflected waves is effective, and various structures have been put into practical use. For example, a 3-stub matcher is often used to prevent reflected waves in a rectangular waveguide system. Three conductor rods having variable insertion lengths called stubs are provided in the rectangular waveguide, and an insertion length of each stub can be adjusted to cancel original reflected waves.

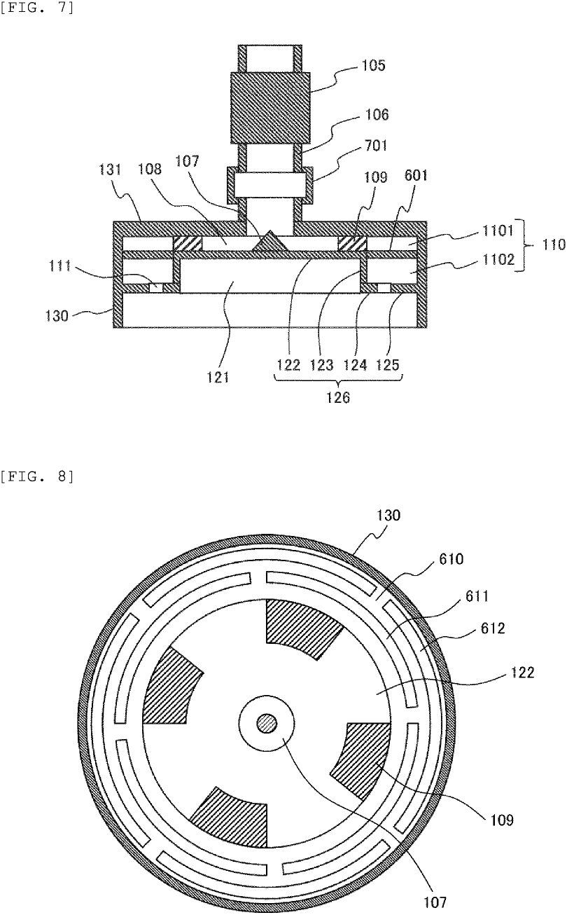

In the present embodiment, when there is a concern that the reflected waves may increase due to the loading of the plate 601 inside the ring resonator 110, the reflected waves can be effectively prevented by providing a discontinuous portion for canceling the reflected waves in the waveguide. FIG. 7 shows an example in which a discontinuous portion 701 is provided in the middle of the circular waveguide 106.

As shown in the first embodiment, the electromagnetic waves propagating in the circular waveguide 106 is circularly polarized by the circularly polarized wave generator 105. The discontinuous portion 701 according to the present embodiment is provided in the middle of the circular waveguide 106, and is implemented by a circular waveguide having an inner diameter larger than that of the circular waveguide 106.

By adjusting an inner diameter, a length, and a connection position with the circular waveguide 106 of the discontinuous portion 701 implemented by the circular waveguide, a magnitude and a phase of the reflected waves generated by the discontinuous portion 701 can be adjusted to cancel the reflected waves caused by the plates 601. Further, the reflected waves caused by a structure other than the plates 601 (for example, the reflected waves generated by the phase adjusting units 109) may be canceled together.

The discontinuous portion 701 needs to have a structure that does not have a non-axisymmetry so as not to hinder circularly polarized waves propagating inside the circular waveguide 106, and in the present embodiment, a circular waveguide having an inner diameter larger than that of the circular waveguide 106 is used. As another structure, a circular waveguide having an inner diameter smaller than that of the circular waveguide 106 may be used.

FIG. 8 shows a plan view of a modification of a conductor plate of a ring resonator corresponding to the cross-sectional view taken along the line BB of FIG. 6A of the microwave plasma etching apparatus in the present embodiment. The same part numbers are assigned to the same configurations as those described with reference to FIGS. 6A and 6B, and the description thereof will be omitted. In the modification, the plurality of the plates 601 of the conductor plate described with reference to FIG. 6B are provided, but in FIG. 8, in order to make configurations of a plurality of slits 611 and 612 easy to understand, the display of the plates 601 of the conductor plate described with reference to FIG. 6B is omitted.

In the modification shown in FIG. 8, a lower surface portion 610 is provided in place of the inner edge portion 124 and the outer edge portion 125 of the inner cavity forming portion 126 of the ring resonator 110 described with reference to FIG. 6B. In the modification, the annular slot antenna 111, which is formed on the lower portion of the ring resonator 110 described in FIG. 6B, is formed on the lower surface portion 610 by the plurality of inner slits 611 and outer slits 612.

As described above, instead of the annular slot antenna 111 described with reference to FIG. 6B, the plurality of inner slits 611 and outer slits 612 as shown in FIG. 8 may be provided.

According to the present embodiment, since the microwaves formed by the electric field in the desired mode can be radiated from the slot antenna 111 to the cavity portion 112, axisymmetric plasma can be generated inside the plasma processing chamber 116, and compared with the case where the plurality of plates 601 are not loaded inside the ring resonator 110, the processing uniformity of the target substrate 117 can be improved.

Further, with the configuration in which the circular waveguide 106 connected to the parallel flat plate line 108 is provided with the discontinuous portion 701 to reduce the reflected waves caused by the plates 601, it is possible to prevent the transmission power from being reduced by the reflected waves, and to prevent an energy efficiency from being lowered by loading the plates 601 inside the ring resonator 110.

The discontinuous portion 701 described in the present embodiment can also be applied to the microwave plasma etching apparatus 100 of FIG. 1 described in the first embodiment. In this case, in the configuration shown in FIG. 1, the discontinuous portion 701 is attached to an intermediate portion of the circular waveguide 106. Accordingly, the reflected waves generated by the phase adjusting units 109 and the like can be reduced.

While the invention made by the inventor has been described in detail based on the embodiment, the invention is not limited to the above-described embodiment, and various modifications can be made without departing from the scope of the invention. For example, the above-described embodiment has been described in detail for easy understanding of the invention, and the invention is not necessarily limited to those including all the configurations described above. In addition, a part of the configuration of each embodiment may be added, deleted, or replaced with another configuration.

### REFERENCE SIGN LIST

100: microwave plasma etching apparatus
101: microwave oscillator
102: isolator
103: automatic matcher
104: circular rectangle converter
105: circularly polarized wave generator
106: circular waveguide
107: matching block
108: parallel flat plate line
109: phase adjusting unit
110: ring resonator
111: slot antenna
112: cavity portion
113: static magnetic field generator
114: microwave introduction window
115: shower plate
116: plasma processing chamber
117: target substrate
118: substrate electrode
121: inner cavity portion
130: vacuum chamber
301: radial slot antenna
302: arc-shaped slot antenna
401: ridge
510: phase adjusting unit
601: plate
701: discontinuous portion

1. A plasma processing apparatus, comprising:
a processing chamber where a sample is to be plasma-processed;
a radio frequency power supply configured to supply a radio frequency power of microwaves for generating plasma;
a ring resonator configured to resonate microwaves propagated through a circular waveguide having a circular cross section such that a mode of the propagated microwaves is a mode having microwaves of m wavelengths in an azimuth direction where m is an integer greater than or equal to 2; and
a dielectric window that is disposed above the processing chamber and allows the propagated microwaves to pass into the processing chamber, wherein
the circular waveguide is configured to propagate the microwaves to the ring resonator through a parallel flat plate line portion, and
the parallel flat plate line portion has a circular upper surface and a circular lower surface, and includes a phase adjuster configured to set a phase of the microwaves propagating to the ring resonator to a predetermined phase.

2. The plasma processing apparatus according to claim 1, wherein
the number of the parallel flat plate line portion is one, and
the phase adjuster is formed of a dielectric material.

3. The plasma processing apparatus according to claim 1, wherein
the phase adjuster is disposed at a connection portion between the parallel flat plate line portion and the ring resonator.

4. The plasma processing apparatus according to claim 3, wherein
the number of the phase adjusters is four.

5. The plasma processing apparatus according to claim 1, wherein
the parallel flat plate line portion includes a metal matching member configured to prevent reflection of the microwaves propagated from the circular waveguide.

6. The plasma processing apparatus according to claim 1, wherein
a slot antenna having an opening portion for radiating the microwaves resonated by the ring resonator is formed in the ring resonator.

7. The plasma processing apparatus according to claim 6, wherein
the opening portion is an annular opening portion.

8. The plasma processing apparatus according to claim 6, wherein
the opening portion is a plurality of opening portions disposed radially.

9. The plasma processing apparatus according to claim 6, wherein
the opening portion is a plurality of arc-shaped opening portions disposed in a circumferential direction.

10. The plasma processing apparatus according to claim 1, wherein
a conductive column that short-circuits the upper surface of the parallel flat plate line portion and the lower surface of the parallel flat plate line portion is disposed next to the phase adjuster.

11. The plasma processing apparatus according to claim 1, wherein
the predetermined phase is a phase that reduces mismatch of an electromagnetic field distribution of the microwaves on a connection surface between the ring resonator and the parallel flat plate line portion.

12. The plasma processing apparatus according to claim 4, further comprising:
a magnetic field forming mechanism configured to form a magnetic field inside the processing chamber.

13. The plasma processing apparatus according to claim 1, wherein
the ring resonator includes a conductor plate.

14. The plasma processing apparatus according to claim 13, wherein
the conductor plate is a plurality of conductor plates disposed along a circumferential direction.

15. A plasma processing apparatus, comprising:
a processing chamber where a sample is to be plasma-processed;
a radio frequency power supply configured to supply a radio frequency power of microwaves for generating plasma;
a ring resonator configured to resonate microwaves propagated through a circular waveguide having a circular cross section such that a mode of the propagated microwaves is a mode having microwaves of m wavelengths in an azimuth direction where m is an integer greater than or equal to 2; and
a dielectric window that is disposed above the processing chamber and allows the microwaves propagated by the ring resonator to pass into the processing chamber, and further comprising:
a parallel flat plate line portion configured to propagate the microwaves propagated from the circular waveguide to the ring resonator, wherein
an upper surface and a lower surface of the parallel flat plate line portion are circular.

16. The plasma processing apparatus according to claim 1, wherein
the ring resonator includes a plurality of plates disposed such that a surface of each is perpendicular to an electric field in the mode having microwaves of m wavelengths in the azimuth direction, and
a material of the plates is a material having a predetermined conductivity.
